(19) United States
(12) Patent Application Publication
(10) Pub. No.: US 2017/0373181 A1
(43) Pub. Date: Dec. 28, 2017

(54) METAL OXIDE THIN FILM TRANSISTORS (TFTS) AND THE MANUFACTURING METHOD THEREOF

(71) Applicant: Shenzhen China Star Optoelectronics Technology Co. Ltd., Shenzhen, Guangdong (CN)

(72) Inventor: Zhiwu WANG, Shenzhen, Guangdong (CN)

(73) Assignee: Shenzhen China Star Optoelectronics Technology Co., Ltd., Shenzhen, Guangdong (CN)

(21) Appl. No.: 15/114,061

(22) PCT Filed: May 26, 2016
(86) PCT No.: PCT/CN2016/083536

§ 371 Date: Jul. 25, 2016

(30) Foreign Application Priority Data
May 5, 2016 (CN) 201610081471.9

(51) Int. Cl. H01L 29/786; H01L 29/51; H01L 29/49; H01L 29/66; H01L 21/34

(52) U.S. Cl. CPC H01L 29/786; H01L 29/66969; H01L 21/34; H01L 29/4908; H01L 29/51

(57) ABSTRACT

The present disclosure relates to a metal oxide TFT and the manufacturing method thereof. The TFT includes a substrate, a buffering layer formed on the substrate, and an active layer formed on the buffering layer. The TFT further includes a source and a drain formed at two lateral sides of the active layer, a gate insulation layer formed on the active layer, a gate formed on the gate insulation layer, and an dielectric layer formed on the gate. The dielectric layer is made by SiOx. The dielectric layer is made by SiOx, instead of SiNx, wherein the content of the hydrogen ion may be lower. Thus, the hydrogen ion may be prevented from being diffused within the active layer so as to avoid the huge electrical leakage, which enhances the electrical performance of the metal oxide TFT.

### BACKGROUND OF THE INVENTION

### 1. Field of the Invention

The present disclosure relates to liquid crystal display technology, and more particularly to a metal oxide TFT and the manufacturing method thereof.

### 2. Discussion of the Related Art

TFT liquid crystal displays (LCDs) is an active-matrix liquid crystal display device, wherein each of the pixels on the display panel is driven by TFTs behind the pixels, and thus the TFT plays an important role to response and color trueness of the LCDs. Usually, the TFTs include a-Si TFT, LTPS TFT, and metal oxide TFT, wherein the main trend relates to adopting the metal oxide to form the trench layer. In particular, by adopting the indium gallium zinc oxide (IGZO), the power consumption of the display panel may be close to the OLED, while the thickness may only be above the OLED for 25%. In addition, the resolution rate may be up to full HD, i.e., 1920*1080P, or even higher than ultra-definition, i.e., 4k*2k. Nevertheless, the cost of the IGZO is relative low.

Currently, the mass production IGZO TFT mainly adopts bottom gate structure, that is, the gate is arranged in a bottom of the TFT. The manufacturing process is complicated, and the cost is high. To reduce the manufacturing cost, the IGZO TFT adopting top gate structure has been proposed, wherein inter layer dielectric (ILD) is made by SiN. In addition, the ILD contacts with the IGZO layer. A doping process is applied to the IGZO layer to transform a portion of the IGZO, such that the source and the drain are formed. The source/drain metal lines may direct connect to the source and the drain to obtain the TFT structure. With such configuration, as the content of the hydrogen (H) of the ILD layer is high, when the doping process is applied, the hydrogen (H) is diffused horizontally within the IGZO layer. The hydrogen (H) may be diffused into the trench layer and the electrical leakage may be too huge. Under the circumstance, the TFT may malfunction. Thus, it is needed to enhance the IGZO TFT having top gate structure so as to overcome the above problems.

### SUMMARY

To overcome the above problems, the metal oxide TFTs and the manufacturing method thereof are proposed to reduce the electrical leakage of the metal oxide TFT having top gate structure so as to prevent the TFT from malfunction.

In one aspect, a metal oxide thin film transistor (TFT) includes: a substrate, a buffering layer formed on the substrate, and an active layer formed on the buffering layer; a source and a drain formed at two lateral sides of the active layer; a gate insulation layer formed on the active layer; a gate formed on the gate insulation layer; and an dielectric layer formed on the gate, and the dielectric layer is made by SiOx.

In one embodiment, the gate insulation layer and the gate are respectively patterned gate insulation layer and the patterned gate, and the gate insulation layer and the gate are manufactured by the same mask process.

In one embodiment, the source and the drain are formed by the following step: adopting the gate as a masking layer, and radiating the portions of the active layer not covered by the gate with laser beams such that the portions of the active layer not covered by the gate are respectively formed to be the source and the drain.

In one embodiment, the step of radiating the portions of the active layer not covered by the gate with laser beams includes: adopting an excimer laser annealing method to radiate on the portions of the active layer not covered by the gate.

In one embodiment, when the dielectric layer is formed on the gate, the dielectric layer is also formed above the buffering layer, the source, and the drain, and the gate, the gate insulation layer, the source, the drain, and the active layer are covered by the dielectric layer.

In one embodiment, the metal oxide TFT further includes a source metal layer and a drain metal layer, a source contact hole and a drain contact hole respectively corresponding to the source and the drain are formed on the dielectric layer to respectively expose a portion of the source and a portion of the drain, the source metal layer contacts with the source via the source contact hole, and the drain metal layer contacts with the drain via the drain contact hole.

In one embodiment, the active layer is an IGZO layer.

In another aspect, a manufacturing method of metal oxide TFTs includes: providing a substrate; depositing a buffering layer on the substrate; forming an active layer on the buffering layer; forming a gate insulation layer on the active layer; forming a gate on the gate insulation layer; forming a source and a drain respectively at two sides of the active layer; and forming an dielectric layer on the gate, and the dielectric layer is made by SiOx.

In one embodiment, after the step of forming the gate insulation layer on the active layer and the step of forming the gate on the gate insulation layer, the method further includes: adopting the same mask process to perform a lithography process and an etching process to the gate insulation layer and the gate so as to obtain the patterned gate insulation layer and the patterned gate.

In one embodiment, the step of forming the source and the drain at two sides of the active layer further includes: adopting the gate as a masking layer, and radiating the portions of the active layer not covered by the gate with laser beams such that the portions of the active layer not covered by the gate are respectively formed to be the source and the drain

In one embodiment, the step of radiating the portions of the active layer not covered by the gate with laser beams includes: adopting an excimer laser annealing method to radiate on the portions of the active layer not covered by the gate.

In one embodiment, when the dielectric layer is formed on the gate, the dielectric layer is also formed above the buffering layer, the source, and the drain, and the gate, the gate insulation layer, the source, the drain, and the active layer are covered by the dielectric layer.

In one embodiment, the metal oxide TFT further includes a source metal layer and a drain metal layer, a source contact hole and a drain contact hole respectively corresponding to the source and the drain are formed on the dielectric layer to respectively expose a portion of the source and a portion of the drain, the source metal layer contacts with the source via the source contact hole, and the drain metal layer contacts with the drain via the drain contact hole.

In one embodiment, the active layer is a patterned active layer.

In one embodiment, the active layer is the pattered active layer after being applied with a lithography process and an etching process.

In one embodiment, the active layer is an IGZO layer.

In view of the above, the dielectric layer may be made by SiOx, instead of SiNx. Regarding the conventional solution, wherein the dielectric layer is made by SiNx, as the content of the hydrogen (H) of the ILD layer is high, when the doping process is applied, the hydrogen (H) is diffused horizontally within the IGZO layer. The hydrogen (H) may be diffused into the trench layer and the electrical leakage may be too huge. Under the circumstance, the TFT may malfunction. By adopting the SiOx, the content of the hydrogen ion may be lower. Thus, the hydrogen ion may be prevented from being diffused within the active layer so as to avoid the huge electrical leakage, which enhances the electrical performance of the metal oxide TFT.

Second, the patterned gate active layer and the gate are manufactured by the same mask process, which is different from the conventional process, i.e., one mask is adopted to pattern one structure. The two structures are manufactured by the same mask process, which not only reduces the number of mask involved, but also simplify the manufacturing steps so as to reduce the manufacturing cost.

Lastly, as the gate arranged on a top operates as a masking layer. The laser beams are adopted to radiate the active layer below the gate, and the excimer laser annealing method is adopted to radiate on the portions of the active layer not covered by the gate. The exposed portions of the active layer are transformed into conductive bodies, i.e., the source and the drain. Thus, instead of depositing a metal layer and applying the lithographic process to the metal layer to form the source and drain, the present disclosure relates to radiating the portions of the active layer not covered by the gate by the laser beams so as to form the source and the drain, which simplifies the complexity of the TFT design so as to simplify the manufacturing steps.

### BRIEF DESCRIPTION OF THE DRAWINGS

FIGS. 1-8 are schematic views showing the manufacturing method of the metal oxide TFTs in accordance with one embodiment.

### DETAILED DESCRIPTION OF THE EMBODIMENTS

Embodiments of the invention will now be described more fully hereinafter with reference to the accompanying drawings, in which embodiments of the invention are shown.

In one embodiment, the manufacturing method of the metal oxide TFT includes the following steps.

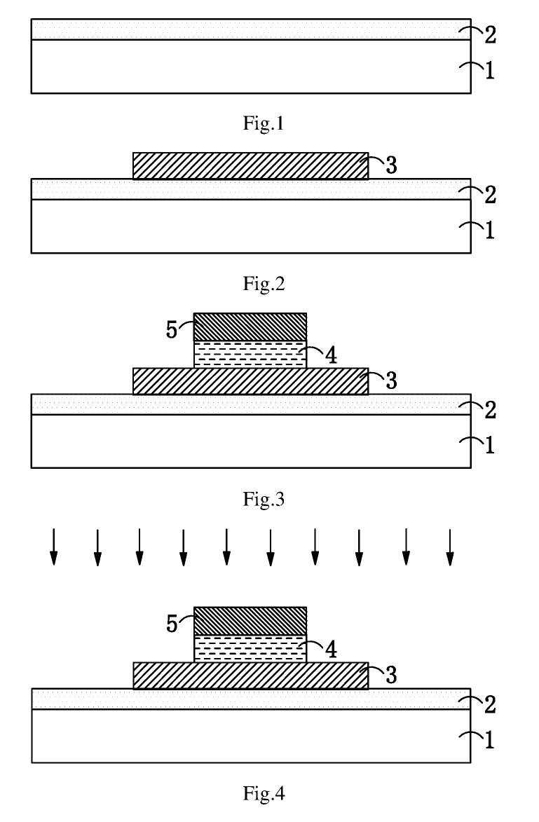

As shown in FIG. 1, providing a substrate 1, and depositing a buffering layer 2 on the substrate 1.

As shown in FIG. 2, depositing an IGZO layer above the buffering layer 2 to be an active layer 3, and applying a lithographic process and an etching process to the active layer 3 to obtain the patterned active layer 3.

As shown in FIG. 3, depositing a gate insulation layer 4 and a gate 5 on the patterned active layer 3 in sequence, and applying the lithographic process and the etching process to the gate insulation layer 4 and the gate 5 by the same mask process (not shown) to obtain the patterned gate insulation layer 4 and the patterned gate 5. In view of FIG. 3, after being patterned, the gate 5 has not completely covered the active layer 3 such that portions at two lateral sides of the active layer 3 are exposed. In the embodiment, only one mask is adopted to pattern the gate insulation layer 4 and the gate 5, which not only conserves the mask, but also excludes the lithography step. As such, the manufacturing method has been simplified, the manufacturing cost of the TFT is reduced, and the manufacturing efficiency is enhanced.

As shown in FIG. 4, the gate 5 is adopted as a mask layer. An excimer laser annealing method is adopted to radiate on the portions of the active layer 3 not covered by the gate 5. As shown in FIG. 5, a source 61 is formed at the left side of the active layer 3 not covered by the gate 5, and a drain 62 is formed at the right side of the active layer 3 not covered by the gate 5. In the embodiment, the laser is adopted to radiate on the active layer 3, such that portions of the active layer are transformed to be the source and the drain, which simplifies the complexity of the TFT design so as to simplify the manufacturing steps.

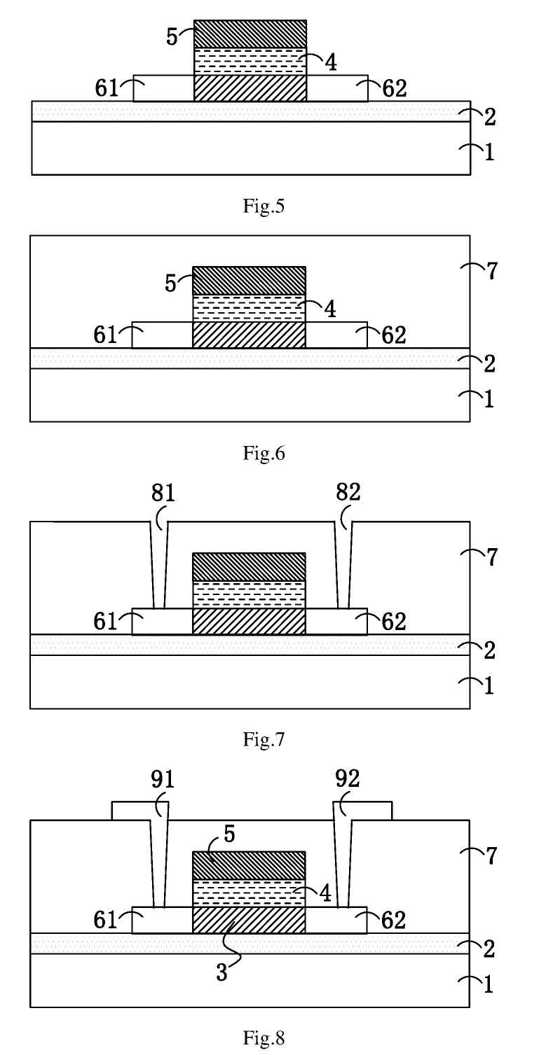

As shown in FIG. 6, an dielectric layer 7 is deposited on the buffering layer 2, the source 61, the drain 62, and the gate 5. The dielectric layer 7 covers the source 61, the drain 62, the gate 5, the gate insulation layer 4, and the active layer 3. In the embodiment, the dielectric layer may be made by SiOx, instead of SiNx, wherein the content of the hydrogen ion may be lower. Thus, the hydrogen ion may be prevented from being diffused within the active layer so as to avoid the huge electrical leakage, which prevents the TFT from malfunction.

As shown in FIG. 7, a source contact hole 81 corresponding to the source 61 is formed within the dielectric layer 7, and the source contact hole 81 exposes a portion of the source 61. A drain contact hole 82 corresponding to the drain 62 is formed within the dielectric layer 7, and the source contact hole 81 exposes a portion of the drain 62.

As shown in FIG. 8, depositing a source metal layer 91 within the source contact hole 81 such that the source metal layer 91 contacts with the source 61, and depositing a drain metal layer 92 within the drain contact hole 82 such that the drain metal layer 92 contacts with the drain 62.

In the present disclosure, the depositing, lithography, etching, and excimer laser annealing process are general processes within the TFT manufacturing field. The steps and corresponding parameters within the above processes may be referenced in general processes, and thus are omitted hereinafter.

Further, the metal oxide TFT manufactured by any one of the above manufacturing method is shown in FIG. 8. The metal oxide TFT includes:

a substrate 1;

a buffering layer 2 formed on a glass substrate;

an patterned active layer 3 formed on the buffering layer 2, and the active layer is an IGZO layer;

a source 61 adjacent to a left side of the active layer 3, and a drain 62 formed adjacent to a right side of the active layer 3;

a patterned gate insulation layer 4 formed on the active layer 3;

a patterned gate 5 formed on the gate insulation layer 4;

an dielectric layer 7 formed on the gate 5, and the dielectric layer 7 is formed above the buffering layer 2, the source 61, and the drain 62, such that the gate 5, the gate insulation layer 4, the source 61, the drain 62, and the active layer 3 are covered by the dielectric layer 7;

a source contact hole 81 corresponding to the source 61 is formed within the dielectric layer 7, and the source contact hole 81 exposes a portion of the source 61, and a drain contact hole 82 corresponding to the drain 62 is formed within the dielectric layer 7, and the source contact hole 81 exposes a portion of the drain 62; and

a source metal layer 91 is deposited within the source contact hole 81 such that the source metal layer 91 contacts with the source 61 via the source contact hole 81, and a drain metal layer 92 is deposited within the drain contact hole 82 such that the drain metal layer 92 contacts with the drain 62 via the drain contact hole 82.

In the embodiment, the dielectric layer may be made by SiOx, instead of SiNx, wherein the content of the hydrogen ion may be lower. Thus, the hydrogen ion may be prevented from being diffused within the active layer so as to avoid the huge electrical leakage, which prevents the TFT from malfunction.

In addition, the patterned gate active layer and the gate are manufactured by the same mask process, which is different from the conventional process, i.e., one mask is adopted to pattern one structure. The two structures are manufactured by the same mask process, which not only reduces the number of mask involved, but also simplify the manufacturing steps so as to reduce the manufacturing cost.

In addition, the source and the drain at two lateral sides of the active layer is obtained by the following method: the gate is adopted as the masking layer, and the excimer laser annealing method is adopted to radiate on the portions of the active layer not covered by the gate. The exposed portions of the active layer are transformed into conductive bodies, i.e., the source at the left side of the active layer, and the drain at the right side of the active layer.

It can be understood that the above descriptions focus on the main body of the metal oxide TFT, however, the metal oxide TFT may include other regular components, and thus are omitted hereinafter.

It is believed that the present embodiments and their advantages will be understood from the foregoing description, and it will be apparent that various changes may be made thereto without departing from the spirit and scope of the invention or sacrificing all of its material advantages, the examples hereinbefore described merely being preferred or exemplary embodiments of the invention.

What is claimed is:

1. A metal oxide thin film transistor (TFT), comprising:
a substrate, a buffering layer formed on the substrate, and an active layer formed on the buffering layer;
a source and a drain formed at two lateral sides of the active layer;
a gate insulation layer formed on the active layer;
a gate formed on the gate insulation layer; and
an dielectric layer formed on the gate, and the dielectric layer is made by SiOx.

2. The metal oxide TFT as claimed in claim 1, wherein the gate insulation layer and the gate are respectively patterned gate insulation layer and the patterned gate, and the gate insulation layer and the gate are manufactured by the same mask process.

3. The metal oxide TFT as claimed in claim 1, wherein the source and the drain are formed by the following step:
adopting the gate as a masking layer, and radiating the portions of the active layer not covered by the gate with laser beams such that the portions of the active layer not covered by the gate are respectively formed to be the source and the drain.

4. The metal oxide TFT as claimed in claim 3, wherein the step of radiating the portions of the active layer not covered by the gate with laser beams comprises:
adopting an excimer laser annealing method to radiate on the portions of the active layer not covered by the gate.

5. The metal oxide TFT as claimed in claim 1, wherein when the dielectric layer is formed on the gate, the dielectric layer is also formed above the buffering layer, the source, and the drain, and the gate, the gate insulation layer, the source, the drain, and the active layer are covered by the dielectric layer.

6. The metal oxide TFT as claimed in claim 1, wherein the metal oxide TFT further comprises a source metal layer and a drain metal layer, a source contact hole and a drain contact hole respectively corresponding to the source and the drain are formed on the dielectric layer to respectively expose a portion of the source and a portion of the drain, the source metal layer contacts with the source via the source contact hole, and the drain metal layer contacts with the drain via the drain contact hole.

7. The metal oxide TFT as claimed in claim 2, wherein the metal oxide TFT further comprises a source metal layer and a drain metal layer, a source contact hole and a drain contact hole respectively corresponding to the source and the drain are formed on the dielectric layer to respectively expose a portion of the source and a portion of the drain, the source metal layer contacts with the source via the source contact hole, and the drain metal layer contacts with the drain via the drain contact hole.

8. The metal oxide TFT as claimed in claim 3, wherein the metal oxide TFT further comprises a source metal layer and a drain metal layer, a source contact hole and a drain contact hole respectively corresponding to the source and the drain are formed on the dielectric layer to respectively expose a portion of the source and a portion of the drain, the source metal layer contacts with the source via the source contact hole, and the drain metal layer contacts with the drain via the drain contact hole.

9. The metal oxide TFT as claimed in claim 4, wherein the metal oxide TFT further comprises a source metal layer and a drain metal layer, a source contact hole and a drain contact hole respectively corresponding to the source and the drain are formed on the dielectric layer to respectively expose a portion of the source and a portion of the drain, the source metal layer contacts with the source via the source contact hole, and the drain metal layer contacts with the drain via the drain contact hole.

10. The metal oxide TFT as claimed in claim 5, wherein the metal oxide TFT further comprises a source metal layer and a drain metal layer, a source contact hole and a drain contact hole respectively corresponding to the source and the drain are formed on the dielectric layer to respectively expose a portion of the source and a portion of the drain, the source metal layer contacts with the source via the source contact hole, and the drain metal layer contacts with the drain via the drain contact hole.

11. The metal oxide TFT as claimed in claim 1, wherein the active layer is an IGZO layer.

12. The metal oxide TFT as claimed in claim 2, wherein the active layer is an IGZO layer.

13. The metal oxide TFT as claimed in claim 3, wherein the active layer is an IGZO layer.

14. The metal oxide TFT as claimed in claim 4, wherein the active layer is an IGZO layer.

15. The metal oxide TFT as claimed in claim 5, wherein the active layer is an IGZO layer.

16. A manufacturing method of metal oxide TFTs, comprising:
providing a substrate;
depositing a buffering layer on the substrate;
forming an active layer on the buffering layer;
forming a gate insulation layer on the active layer;
forming a gate on the gate insulation layer;
forming a source and a drain respectively at two sides of the active layer;
forming an dielectric layer on the gate, and the dielectric layer is made by SiOx.

17. The manufacturing method as claimed in claim 16, wherein after the step of forming the gate insulation layer on the active layer and the step of forming the gate on the gate insulation layer, the method further comprises:
adopting the same mask process to perform a lithography process and an etching process to the gate insulation layer and the gate so as to obtain the patterned gate insulation layer and the patterned gate.

18. The manufacturing method as claimed in claim 16, wherein the step of forming the source and the drain at two sides of the active layer further comprises:
adopting the gate as a masking layer, and radiating the portions of the active layer not covered by the gate with laser beams such that the portions of the active layer not covered by the gate are respectively formed to be the source and the drain.
